(19) United States
(12) Patent Application Publication
(10) Pub. No.: US 2014/0070404 A1
(43) Pub. Date: Mar. 13, 2014

(54) SEMICONDUCTOR PACKAGE STRUCTURE AND INTERPOSER THEREFOR

(71) Applicants: Shing-Ren Sheu, Taoyuan County (TW); Shih-Chieh Huang, Hsinchu City (TW); Ting-Chao Chou, Taoyuan County (TW); Shang-Chi Wu, Hsinchu City (TW)

(72) Inventors: Shing-Ren Sheu, Taoyuan County (TW); Shih-Chieh Huang, Hsinchu City (TW); Ting-Chao Chou, Taoyuan County (TW); Shang-Chi Wu, Hsinchu City (TW)

(21) Appl. No.: 13/612,820

(22) Filed: Sep. 12, 2012

(51) Int. Cl. H01L 23/498

(52) U.S. Cl. 257/737; 257/E23.068

(57) ABSTRACT

An interposer for a semiconductor package structure includes a base substrate, a plurality of passive devices formed on the base substrate, and an identification (ID) code. The base substrate includes a first surface and an opposite second surface. The ID code is formed on the first surface or the second surface of the base substrate.

### BACKGROUND OF THE INVENTION

1. Field of the Invention

The invention relates to a semiconductor package structure and an interposer therefor, and more particularly, to a semiconductor package structure having stacked chips and an interposer for the semiconductor package structure.

2. Description of the Prior Art

Package stacking technology may involve stacking multiple semiconductor chips to achieve high level of integration in semiconductor devices. Thus through silicon via (hereinafter abbreviated as TSV) structure, and interpose with through silicon interposer (TSI) structure are used to provide electrical connections for the stacked chips. By involving those approaches, the spacing distance between chips is reduced and the size of the semiconductor package structure is shrunk while electrical performance and operation frequency of the semiconductor package structure are both improved.

Though the TSV structures and the interposer realize the high density for horizontal or vertical chip stack, it is very difficult to detect the electrical continuity of the interposer until the whole semiconductor package structure is accomplished. Accordingly, it is impossible to trace back to which lot the defective interposer belong and in which process the defective interposer is fabricated.

### SUMMARY OF THE INVENTION

According to the claimed invention, an interposer for a semiconductor package structure is provided. The interposer includes a base substrate, a plurality of passive devices positioned on the base substrate, and an identification (ID) code formed on the base substrate.

According to the claimed invention, a semiconductor package structure is provided. The semiconductor package structure includes at least a function die, a carrier substrate, and at least an interposer positioned in between the function die and the carrier substrate. The interposer electrically connects the function die and the carrier substrate. The interposer further includes an ID code formed thereon.

According to the semiconductor package structure and the interposer for the semiconductor package structure provided by the present invention, the ID code is positioned on the interposer. Accordingly, the defective interposer is easily recognized as soon as the interposer is failed in the test. And thus the lot to which the defective interposer belongs is easily traced back. Consequently, the fabrication process can be checked or calibrated immediately. Therefore the yield of the fabrication process for the semiconductor package structure is improved and the cost is reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional view of an interposer for a semiconductor package structure provided by a preferred embodiment of the present invention.

FIGS. 2-4 are plan views illustrating interposers for semiconductor package structures provided by different preferred embodiments of the present invention.

FIG. 5 is a schematic drawing illustrating a semiconductor package structure provided by a preferred embodiment of the present invention.

### DETAILED DESCRIPTION

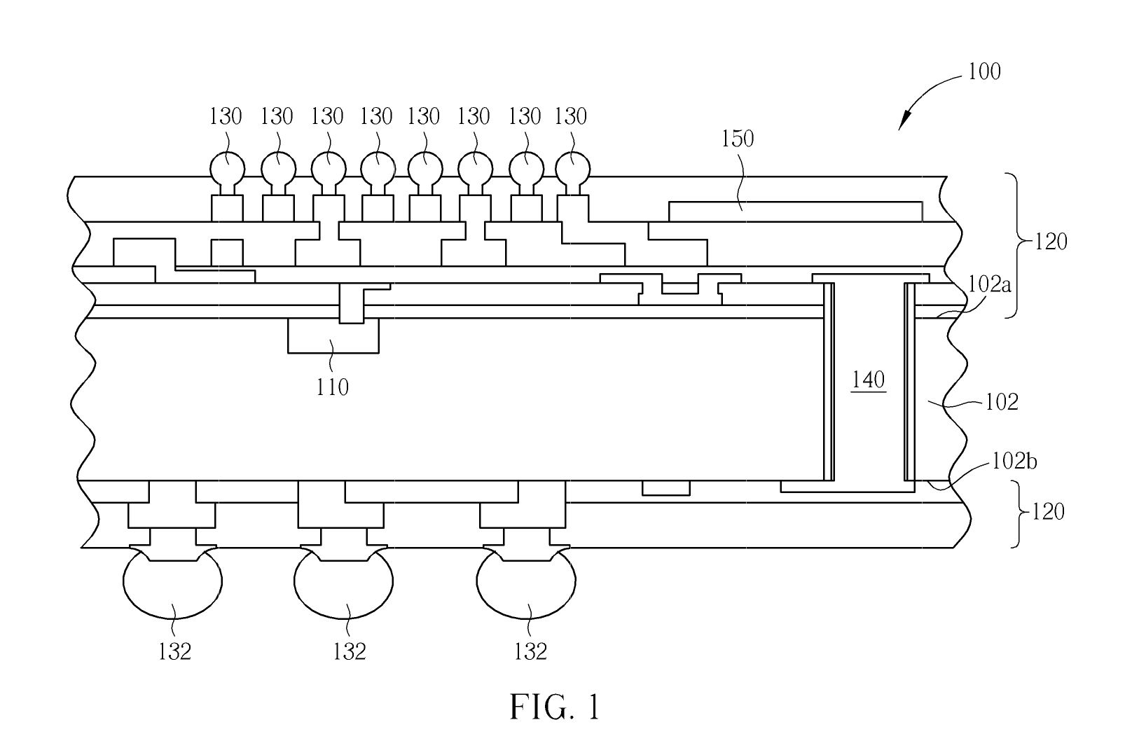

Please refer to FIG. 1, which is a cross-sectional view of an interposer for a semiconductor package structure provided by a preferred embodiment of the present invention. As shown in FIG. 1, the interposer 100 provided by the preferred embodiment includes a base substrate 102. The base substrate 102 can be any suitable substrate, for example but not limited to a silicon substrate or a glass substrate. The base substrate 102 includes a first surface 102a and an opposite second surface 102b. The interposer 100 further includes a plurality of passive devices 110 such as capacitors, resistors, inductors, transformers, etc. There is no active device in the interposer 100. As shown in FIG. 1, the interposer 100 further includes a plurality of redistribution layers (hereinafter abbreviated as RDLs) 120. The RDLs 120 are formed on the first surface 102a and the second surface 102b of the base substrate 102, respectively. Furthermore, the interposer 100 includes a plurality of micro bumps 130 formed on the first surface 102a of the base substrate 102 and a plurality of bumps 132 formed on the second surface 102b of the base substrate 102. More important, the interposer 100 provided by the preferred embodiment includes a plurality of TSV structures 140 electrically connecting the micro bumps 130 to the bumps 132.

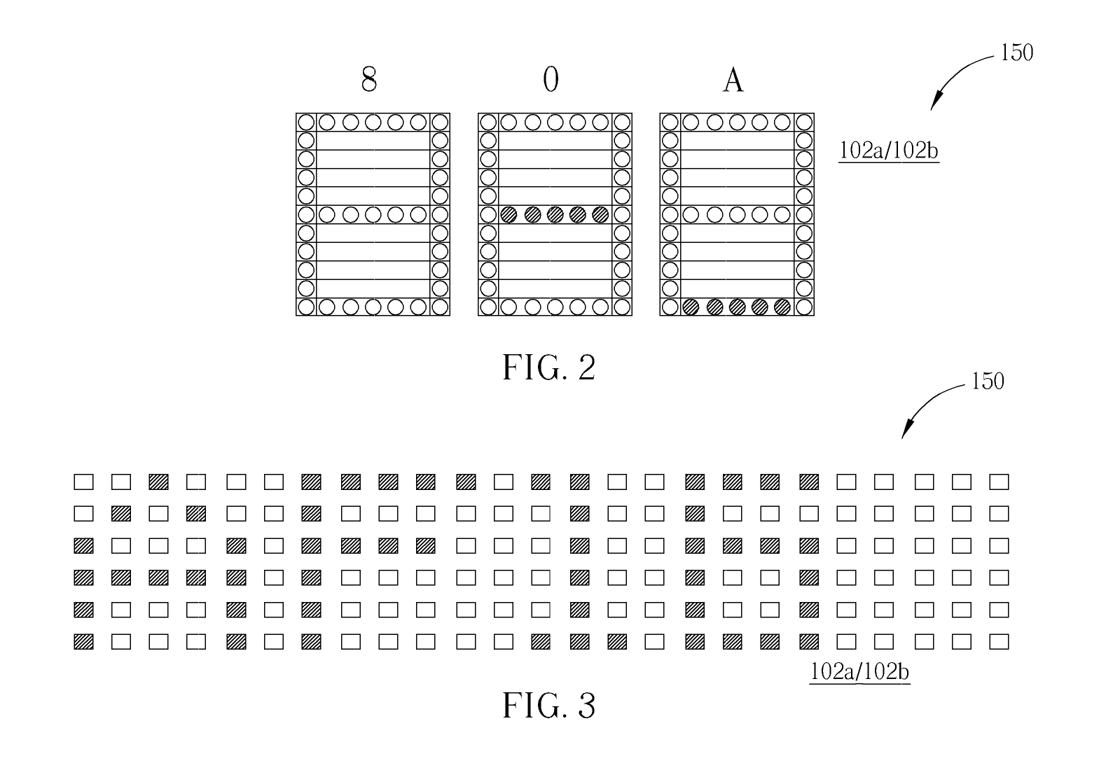

Please refer to FIGS. 2-4, which are plan views illustrating interposers for semiconductor package structures provided by different preferred embodiments of the present invention. As shown in FIG. 2, the interposer 100 provided by the preferred embodiment further includes an ID code 150 formed on the base substrate 102. It is noteworthy that the ID code 150 can be formed on the first surface 102a or the second surface 102b of the base substrate 102, depending on different process or product requirement. As shown in FIG. 2 and FIG. 3, the ID code 150 provided by the preferred embodiment includes a metal pattern. The metal pattern is formed by: forming a metal array configuration on the first surface 102a or the second surface 102b and then trimming certain metal layers by LASER (emphasized by the slash segments in FIG. 2 and FIG. 3). Thus a metal pattern having predetermined design is obtained and serves as the ID code 150 in the preferred embodiment. It is noteworthy that the metal pattern, which is the ID code 150, can be formed simultaneously with forming the passive devices 110, the metal lines in the RDLs 120, an under bump metallization (UMB) (not shown) under the micro bumps 130/the bumps 132, or the micro bumps 130/the bumps 132. The ID code 150 can even be formed simultaneously with forming the TSV structures 140. In other words, the ID code 150 can be formed on the surface 102a/102b or above the surface 102a/102b of the base substrate 102 simultaneously with forming the aforementioned elements depending on the process or product requirement. As shown in FIG. 2, the ID code 150 of the preferred embodiment includes the metal pattern showing “80A”; as shown in FIG. 3, the ID code 150 of the preferred embodiment includes the metal pattern showing “AF16”. The ID codes 150 having specific designs as shown in FIG. 2 and FIG. 3 are read by an optical microscope or an electrical test.

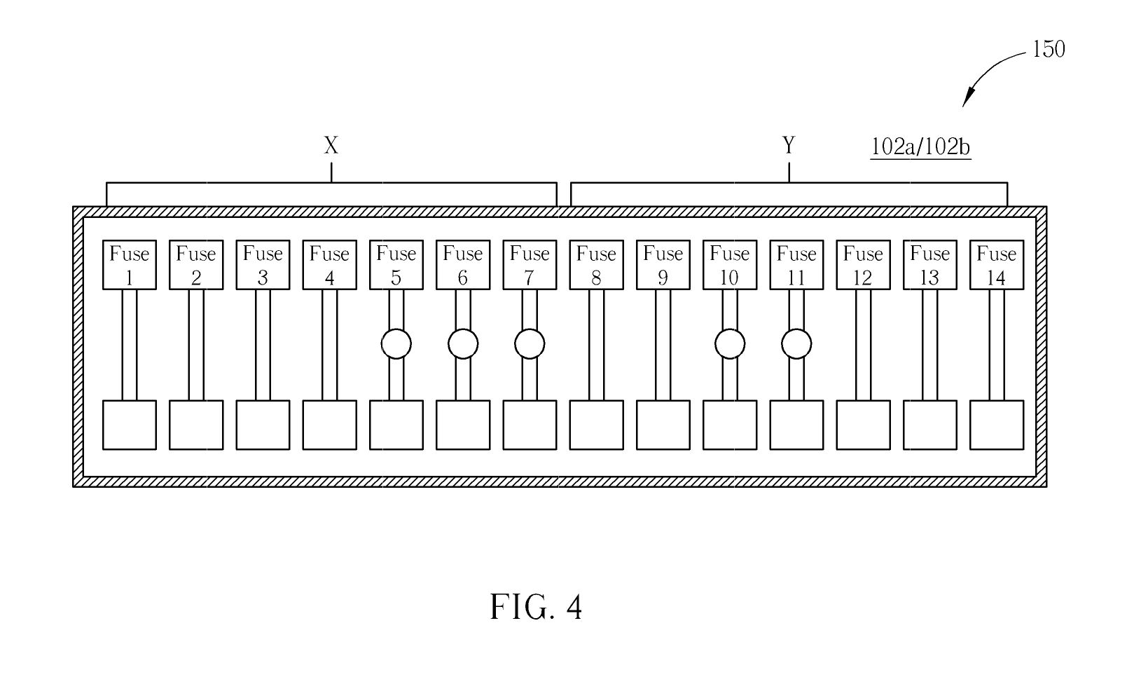

Please refer to FIG. 4. The ID code 150 of another preferred embodiment can be formed on the first surface 102a or the second surface 102b of the base substrate 102. As shown in FIG. 4, the ID code 150 includes a plurality of fuses 152 according to the preferred embodiment. Portions of the fuses 152 are then cut off by Laser zip or proper circuit generating electro-migration (EM) effect, and thus obtain open circuit conditions. Consequently, the ID code 150 is formed on the interposer 100 as show in FIG. 4. In other words, the fuses 152 of the preferred embodiment can be thermal fuses or e-fuses. As shown in FIG. 4, the ID code 150 exemplarily includes Group X and Group Y, which respectively includes seven fuses 152. In Group X, the last three fuses 152 are cut off while the third, the fourth, and the sixth fuses 152 in Group Y are cut off. Accordingly, the ID code 150 having specific design (portions of the fuses 152 are cut off and portions of the fuses remain closed circuit) can be read by an optical microscope. In addition, since the fuses 152 remain closed circuit provides electrical continuity, the ID code 150 of the preferred embodiment is preferably read by an electrical test.

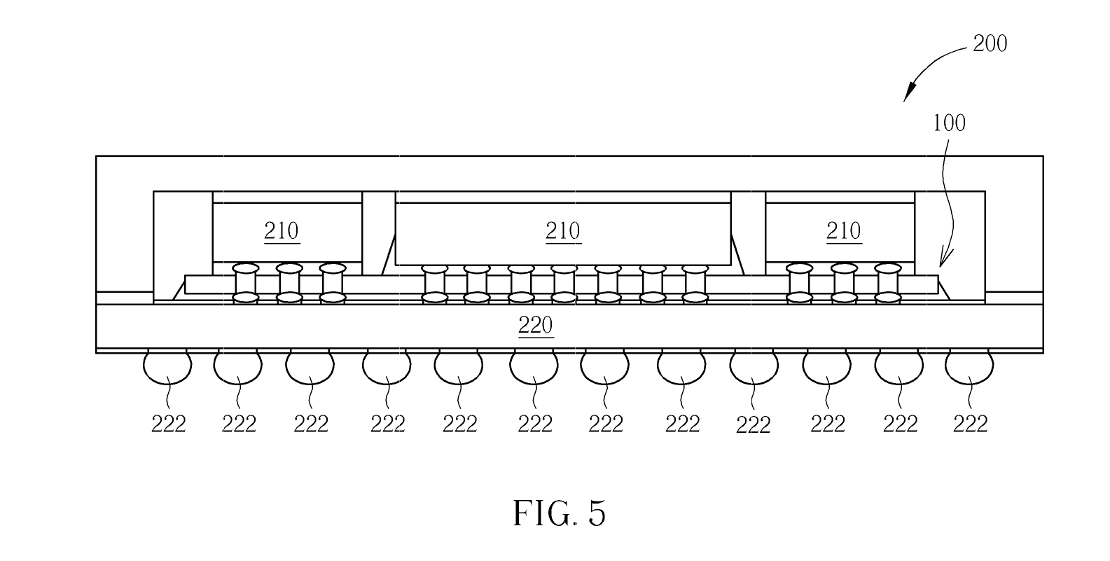

Please refer to FIG. 5, which is a schematic drawing illustrating a semiconductor package structure provided by a preferred embodiment of the present invention. As shown in FIG. 5, the semiconductor package structure 200 provided by the preferred embodiment includes at least a function die 210, which includes, for example but not limited to, a central processing unit (CPU) chip or a dynamic random access memory (DRAM) chip. According to the preferred embodiment, the function die 210 itself can include TSV structures (not shown), too. The semiconductor package structure 200 further includes an interposer 100 including a base substrate 102, passive devices 110, RDLs 120, micro bumps 130, bumps 132, TSV structures 140, and an ID code 150. Since those elements are described as above, those details are omitted from the following description and FIG. 5 in the interest of brevity. As shown in FIG. 5, the function dies 210 are horizontally stacked on the interposer 100. The micro bumps 130 formed in between the function die 210 and the base substrate 100 provide electrical connection between the function dies 210 and the interposer 100. The semiconductor package structure 200 of the preferred embodiment further includes a carrier substrate 220. The carrier substrate 220 includes a laminate substrate or a ceramic substrate, but not limited to this. The carrier substrate 200 further includes a plurality of solder balls 222 for providing electrical connections between the semiconductor package structure 200 and other outer circuits. As shown in FIG. 5, the bumps 132 formed in between the base substrate 100 and the carrier substrate 220 provide electrical connection between the interposer 100 and the carrier substrate 220. Briefly speaking, the interposer 100 positioned in between the function dies 210 and the carrier substrate 220 electrically connects the function dies 210 and the carrier substrate 220. Through the micro bumps 130, the TSV structures 140, and the bumps 132, different function dies 120 are integrated on the interposer 100 and electrically connected to the carrier substrate 220. Such semiconductor package structure 200 has advantages of not only high density and high level of integration, but also low process risk and superior stress control for the interposer 100.

Accordingly, since electrical continuity and electrical performance of the interposer are detected only after accomplishing the semiconductor package structure, the present invention provides the ID code formed on the interposer. Therefore the defective interposer is easily recognized as soon as the interposer is failed in the test. And thus the lot to which the defective interposer belongs is easily traced back. Consequently, the fabrication process can be checked or calibrated immediately. Therefore the yield of the fabrication process for the semiconductor package structure is improved and the cost is reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An interposer for a semiconductor package structure comprising:
a base substrate;
a plurality of passive devices positioned on the base substrate; and
an identification (ID) code formed on the base substrate.

2. The interposer for the semiconductor package structure according to claim 1, wherein the ID code comprises a metal pattern formed on a surface of the base substrate.

3. The interposer for the semiconductor package structure according to claim 2, wherein the metal pattern is read by an optical microscope or an electrical test.

4. The interposer for the semiconductor package structure according to claim 1, wherein the ID code comprises a plurality of fuses positioned on a surface of the base substrate.

5. The interposer for the semiconductor package structure according to claim 4, wherein the fuses are read by an optical microscope or an electrical test.

6. The interposer for the semiconductor package structure according to claim 1, further comprising a plurality of redistribution layers (RDLs) formed on a first surface and a second surface of the base substrate, respectively.

7. The interposer for the semiconductor package structure according to claim 6, further comprising a plurality of micro bumps formed on the first surface of the base substrate and a plurality of bumps formed on the second surface of the base substrate.

8. The interposer for the semiconductor package structure according to claim 7, further comprising a plurality of through silicon via (TSV) structures electrically connecting the micro bumps to the bumps.

9. The interposer for the semiconductor package structure according to claim 1, wherein the base substrate comprises a silicon substrate or a glass substrate.

10. A semiconductor package structure comprising:
at least a function die;
a carrier substrate; and
at least an interposer positioned in between the function die and the carrier substrate, the interposer electrically connecting the function die and the carrier substrate, and the interposer comprising an identification (ID) code formed thereon.

11. The semiconductor package structure according to claim 10, wherein the interposer further comprise a base substrate.

12. The semiconductor package structure according to claim 11, wherein the base substrate comprises a silicon substrate or a glass substrate.

13. The semiconductor package structure according to claim 11, wherein the interposer further comprises a plurality of redistribution layers (RDLs) formed on two opposite surfaces of the base substrate, respectively.

14. The semiconductor package structure according to claim 13, wherein the interposer further comprises a plurality of micro bumps formed in between the base substrate and the function die, and a plurality of bumps formed in between the base substrate and the carrier substrate.

15. The semiconductor package structure according to claim 14, wherein the interposer further comprises a plurality of through silicon via structures electrically connecting the micro bumps to the bumps.

16. The semiconductor package structure according to claim 10, wherein the ID code comprises a metal pattern formed on a surface of the interposer.

17. The semiconductor package structure according to claim 16, wherein the metal pattern is read by an optical microscope or an electrical test.

18. The semiconductor package structure according to claim 10, wherein the ID code comprises a plurality of fuses formed on a surface of the interposer.

19. The semiconductor package structure according to claim 10, wherein the fuses are read by an optical microscope or an electrical test.

20. The semiconductor package structure according to claim 10, wherein the interposer further comprises a plurality of passive devices.
